(19) United States
(12) Patent Application Publication
(10) Pub. No.: US 2008/0106358 A1
(43) Pub. Date: May 8, 2008

(54) ELECTRONIC TUNER AND ELECTRONIC DEVICE

(76) Inventor: Yoshitaka KATAGIRI, Osaka (JP)

Correspondence Address: BIRCH STEWART KOLASCH & BIRCH, PO BOX 747, FALLS CHURCH, VA, 22040-0747, US

(21) Appl. No.: 11/935,575

(22) Filed: Nov. 6, 2007

(30) Foreign Application Priority Data
Nov. 7, 2006 (JP) 2006-301797

(51) Int. Cl. H05K 9/00

(52) U.S. Cl. 334/85; 361/816

(57) ABSTRACT

In one embodiment of the present invention, an electronic tuner is provided with a case configured with a frame-like outer circumferential portion and a lid portion that covers a space formed by the outer circumferential portion, and an elastic grounding piece formed by cutting open a portion of the case in the shape of a tongue piece is caused to protrude outside of the case, thus grounding the elastic grounding piece to a grounding portion of an external electronic device.

### BACKGROUND OF THE INVENTION

This application claims priority under 35 U.S.C. § 119(a) on Japanese Patent Application No. 2006-301797 filed in Japan on Nov. 7, 2007, the entire contents of which are hereby incorporated by reference.

The present invention relates to an electronic tuner grounded to an electronic device using an elastic grounding piece caused to protrude from a case, and an electronic device equipped with such an electronic tuner.

In an electronic tuner equipped with an electronic device, as a method for suppressing a beat due to noise introduced to the electronic tuner from the electronic device, unnecessary radiation generated from the electronic tuner, or the like, it is known to perform grounding reinforcement at an appropriate location between the electronic tuner and the electronic device. A conventional example of a means for performing grounding reinforcement is described below with reference to FIGS. 11 and 12.

FIG. 11 is a side view that illustrates the configuration of a grounding reinforcement of an electronic tuner according to Conventional Example 1.

An electronic tuner 101 according to Conventional Example 1 is grounded to a device component 120 (an electronic device 102) via a gasket 103 provided in a case 110, at a position different from the disposed position of a tuner terminal 101t. Also, the electronic tuner 101 is grounded to the device component 120 (the electronic device 102) via an externally attached spring 104 provided in the case 110. Grounding reinforcement is achieved using the conventional gasket 103, the externally attached spring 104, and the like in this manner.

However, because the gasket 103, the externally attached spring 104, and the like are relatively expensive components, and a separate step is necessary for installation, these components increase the cost of assembly, and therefore are a primary cause of increased costs.

FIG. 12 is an explanatory diagram that illustrates the configuration of grounding reinforcement of an electronic tuner according to Conventional Example 2, and is a transparent side view that transparently shows the inside of the case.

In an electronic tuner 101 according to Conventional Example 2, a tuner substrate 105 is disposed inside of a case 110 that is configured with an outer circumferential portion 111 and a lid portion 112. An elastic grounding piece 106 provided in a portion of the lid portion 112 is put in contact with the tuner substrate 105 or a chassis angle of the electronic tuner 101, and thus the elastic grounding piece 106 is a means for configuring the entire electronic tuner 101 (the inside of the electronic tuner 101) as a ground circuit.

An example disclosing a case grounding system is given, for example, in JP H4-107885U.

As described above, in the conventional technology, when establishing grounding reinforcement it is necessary to newly install a separate member, leading to increases in component cost and assembly cost, and impairing productivity, so there is the problem that costs are increased. Also, because a separate member is employed, there is a risk of a processing mistake such as that installation will be forgotten, or that installation will be defective, so that the separate member becomes the cause of a secondary defect.

### SUMMARY OF THE INVENTION

The present invention was made in view of such circumstances, and it is an object thereof to provide an electronic tuner in which by putting a elastic grounding piece formed using a portion of a case in contact with a grounding portion of an electronic device (an electronic component), it is possible to perform grounding reinforcement with a simple structure and low cost.

It is another object of the present invention to provide an electronic device in which grounding reinforcement has been performed, due to equipping the electronic device with an electronic tuner according to the present invention.

The present invention provides an electronic tuner provided with a case having a frame-like outer circumferential portion and a lid portion that covers a space formed by the outer circumferential portion, in which an elastic grounding piece formed by cutting open a portion of the case in the shape of a tongue piece is caused to protrude to the outside of the case, thus grounding the elastic grounding piece to a grounding portion of an external electronic device.

With this configuration, grounding of the electronic tuner to the grounding portion of the electronic device is easy, and it is possible to reliably reinforce grounding of the electronic tuner and the electronic device with a simple configuration.

Also, in the electronic tuner according to the present invention, the elastic grounding piece has a bent portion between a tip portion and a base, the tip portion being put in contact with the grounding portion, and the bent portion being put in contact with a grounding point inside of the case.

With this configuration, it is possible to easily obtain grounding to the grounding portion with the elastic grounding piece having a simple structure, and because grounding to the grounding point can also be obtained, it is further possible to insure firm and stable grounding.

Also, in the electronic tuner according to the present invention, the elastic grounding piece has a bent portion between a tip portion and a base, the tip portion being put in contact with a grounding point inside of the case, and the bent portion being put in contact with the grounding portion.

With this configuration, it is possible to easily obtain grounding to the grounding portion with the elastic grounding piece having a simple structure, and because grounding to the grounding point can also be obtained, it is further possible to insure firm and stable grounding.

Also, in the electronic tuner according to the present invention, the elastic grounding piece has an outside tongue piece used to configure an outer circumference and an inside tongue piece formed on the inside of the outside tongue piece, the outside tongue piece being put in contact with the grounding portion, and the inside tongue piece being put in contact with a grounding point on the inside of the case.

With this configuration, it is possible to obtain grounding to the grounding portion with the elastic grounding piece (the outside tongue piece) having a simple structure and a comparatively large surface area, and it is possible to obtain grounding according to the state of the grounding portion and the grounding point.

Also, in the electronic tuner according to the present invention, the elastic grounding piece has an outside tongue piece used to configure an outer circumference and an inside tongue piece formed on the inside of the outside tongue piece, the outside tongue piece being put in contact with a grounding point on the inside of the case, and the inside tongue piece being put in contact with the grounding portion.

With this configuration, it is possible to obtain grounding to the grounding point with the elastic grounding piece (the outside tongue piece) having a simple structure and a comparatively large surface area, and it is possible to obtain grounding according to the state of the grounding portion and the grounding point.

Also, in the electronic tuner according to the present invention, the elastic grounding piece is formed in the lid portion.

With this configuration, because the elastic grounding piece is formed in the lid portion, which has a greater surface area than the outer circumferential portion, grounding to the grounding portion of the electronic device is very easy.

Also, in the electronic tuner according to the present invention, the elastic grounding piece is formed in the outer circumferential portion.

With this configuration, in all directions of the frame shape of the outer circumferential portion, it is possible to obtain grounding to the grounding portion of the electronic device, and so it is possible to obtain grounding according to the position of the grounding portion and the grounding point.

Also, the electronic device according to the present invention is an electronic device equipped with an electronic tuner having a case, the electronic tuner being an electronic tuner according to the invention.

With this configuration, it is possible to provide an electronic device that is equipped with an electronic tuner in which grounding is reinforced, so that the electronic device has grounding with high reliability.

### BRIEF DESCRIPTION OF THE DRAWINGS

FIG. 1 is a front view that shows an elastic grounding piece formed in a lid portion of an electronic tuner according to Embodiment 1 of the present invention.

FIG. 2 is a perspective view that shows the elastic grounding piece formed in the lid portion of the electronic tuner according to Embodiment 1 of the present invention.

FIG. 3 is a side view that shows a state in which the electronic tuner according to Embodiment 1 of the present invention has been grounded to a device component of an electronic device.

FIG. 4 is an explanatory diagram that illustrates an elastic grounding piece of an electronic tuner according to Embodiment 2 of the present invention, and is a side view that shows a state in which a tip portion of an elastic grounding piece has been grounded to a device component of an electronic device.

FIG. 5 is an explanatory diagram that illustrates the elastic grounding piece of the electronic tuner according to Embodiment 2 of the present invention, and is a side view that shows a state in which a bent portion of the elastic grounding piece has been grounded to the device component of the electronic device.

FIG. 6 is a side view that shows a state in which an outside tongue piece of an elastic grounding piece of an electronic tuner according to Embodiment 3 of the present invention has been grounded to a device component of an electronic device.

FIG. 7 is an enlarged perspective view that shows an enlargement of the elastic grounding piece of the electronic tuner according to Embodiment 3 of the present invention.

FIG. 8 is a side view that shows a state in which an inside tongue piece of the elastic grounding piece of the electronic tuner according to Embodiment 3 of the present invention has been grounded to the device component of the electronic device.

FIG. 9 is an enlarged perspective view that shows an enlargement of the elastic grounding piece of the electronic tuner according to Embodiment 3 of the present invention.

FIG. 10 is a perspective view that illustrates an electronic tuner according to Embodiment 4 of the present invention.

FIG. 11 is a side view that illustrates the configuration of grounding reinforcement of an electronic tuner according to Conventional Example 1.

FIG. 12 is an explanatory diagram that illustrates the configuration of grounding reinforcement of an electronic tuner according to Conventional Example 2, and is a transparent side view that transparently shows the inside of the case.

### DESCRIPTION OF THE PREFERRED EMBODIMENTS

Hereinafter, embodiments of the present invention will be described in detail with reference to the accompanying drawings.

### Embodiment 1

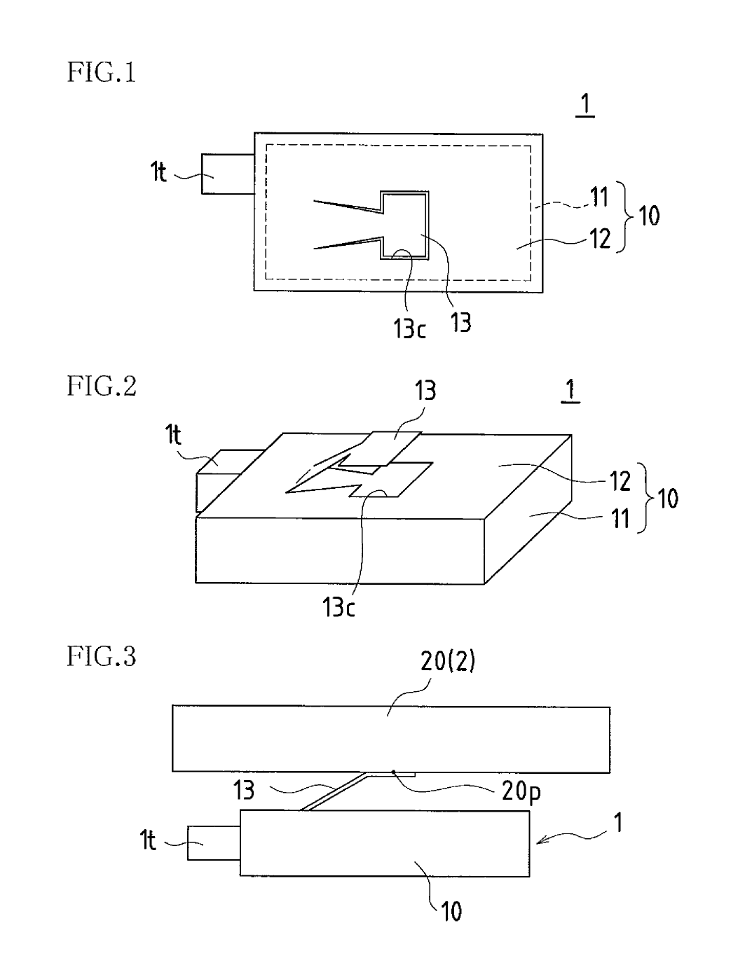

FIG. 1 is a front view that shows an elastic grounding piece formed in a lid portion of an electronic tuner according to Embodiment 1 of the present invention, and FIG. 2 is a perspective view that shows the elastic grounding piece formed in the lid portion of the electronic tuner according to Embodiment 1 of the present invention. FIG. 3 is a side view that shows a state in which the electronic tuner according to Embodiment 1 of the present invention has been grounded to a device component of an electronic device.

In an electronic tuner 1 according to the present embodiment, a case 10 is provided. A tuner terminal it is fixed to the case 10, and inside of the case 10 a tuner substrate (not shown) is housed. The case 10 is configured with a frame-like outer circumferential portion 11, and a lid portion 12 that covers a space formed by the outer circumferential portion 11. Also, the case 10 is mounted to an electronic device 2 (a device component 20), and by functioning as the electronic tuner 1, operates the electronic device 2.

The case 10 is constituted from, for example, metal plate such as aluminum, because it is necessary to electromagnetically shield the tuner substrate in order to prevent the effects of surrounding electromagnetic waves. The case 10 has an elastic grounding piece 13 formed by cutting open a portion (for example, the lid portion 12) of the case 10 in the shape of a tongue piece. The elastic grounding piece 13 is caused to protrude to the outside by bending from a cut-open portion 13c of the case 10, and is grounded by being put in contact with a grounding portion 20p of the electronic device 2 (the device component 20 that constitutes the electronic device 2).

The elastic grounding piece 13 constituted from metal plate has elasticity, so it is possible to reliably and firmly make contact with the grounding portion 20p, and thus it is possible to realize grounding without employing another component. Accordingly, there is no need at all for soldering, installation of another component, or the like in an assembly process for achieving grounding, and so it is possible to reliably prevent the occurrence of processing defects in an assembly process for achieving grounding.

That is, with this configuration, a gasket or the like for achieving grounding is unnecessary, so assembly can be performed simply. Thus, grounding of the electronic tuner 1 to the grounding portion 20p of the electronic device 2 is easy, and it is possible to reliably reinforce grounding of the electronic tuner 1 and the electronic device 2 with a simple configuration.

The shape of the elastic grounding piece 13 can easily be set by appropriately setting the shape of the cut-open portion 13c and then performing a cutting-open process, and thus it is easily possible to adopt a shape with which optimum grounding to the grounding portion 20p is possible. Because the material of the case 10 is employed as-is, a separate member is not necessary, nor is an additional assembly step of assembling a separate member necessary, and so it is possible to reinforce grounding with a simple configuration and low cost.

Also, because the elastic grounding piece 13 is formed in the lid portion 12, which has a greater surface area than the outer circumferential portion 11, grounding to the grounding portion 20p of the electronic device 20 is very easy.

### Embodiment 2

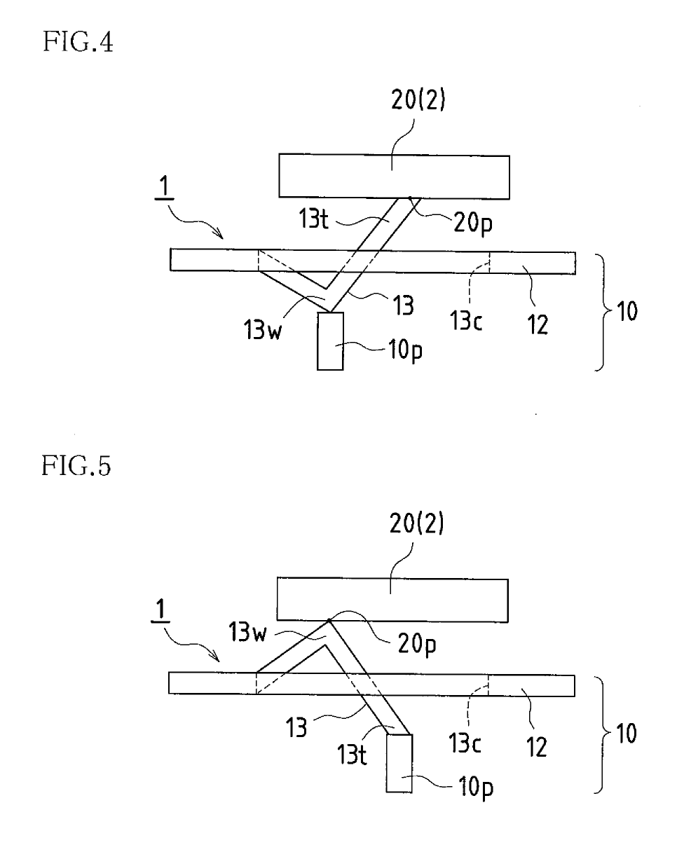

Embodiment 2 will be described with reference to FIGS. 4 and 5.

FIG. 4 is an explanatory diagram that illustrates an elastic grounding piece of an electronic tuner according to Embodiment 2 of the present invention, and is a side view that shows a state in which a tip portion of an elastic grounding piece has been grounded to a device component of an electronic device.

In an elastic grounding piece 13 according to the present embodiment, a bent portion 13w is formed in the middle of the elastic grounding piece 13, which has the shape of a tongue piece. By changing the bend position, it is possible to vary the position where the bent portion 13w is grounded. The basic configuration of the electronic tuner 1 according to the present embodiment is the same as in Embodiment 1, so mainly the differing points will be described here.

The elastic grounding piece 13 of the electronic tuner 1 shown in FIG. 4 has the bent portion 13w between a tip portion 13t and a base, and the bent portion 13w is formed facing the inside of the case 10, so that the tip portion 13t makes contact with the grounding portion 20p of the electronic device 2 (the electronic component 20), and the bent portion 13w makes contact with a grounding point 10p inside of the case 10.

That is, a configuration is adopted in which, in a state with the bent portion 13w disposed to the inside of the lid portion 12 (the case 10), the elastic grounding piece 13 (the tip portion 13t) is caused to protrude to the outside of the case 10 (the lid portion 12).

With this configuration, it is possible to obtain grounding to the grounding portion 20p with the elastic grounding piece 13 having a simple structure, and because grounding to the grounding point 10p can also be obtained, it is further possible to insure firm and stable grounding.

FIG. 5 is an explanatory diagram that illustrates the elastic grounding piece of the electronic tuner according to Embodiment 2 of the present invention, and is a side view that shows a state in which a bent portion of the elastic grounding piece has been grounded to the device component of the electronic device. This is a modified example of the electronic tuner 1 shown in FIG. 4, and so mainly the points that differ from FIG. 4 will be described here.

The elastic grounding piece 13 of the electronic tuner 1 shown in FIG. 5 has the bent portion 13w between the tip portion 13t and the base, and the bent portion 13w is formed facing the outside of the case 10, so that the tip portion 13t makes contact with the grounding point 10p inside of the case 10, and the bent portion 13w makes contact with the grounding portion 20p of the electronic device 2 (the electronic component 20).

That is, a configuration is adopted in which, in a state with the tip portion 13t disposed to the inside of the lid portion 12 (the case 10), the elastic grounding piece 13 (the bent portion 13w) is caused to protrude to the outside of the case 10 (the lid portion 12).

With this configuration, it is possible to obtain grounding to the grounding portion 20p with the elastic grounding piece 13 having a simple structure, and because grounding to the grounding point 10p can also be obtained, it is further possible to insure firm and stable grounding.

As shown in FIGS. 4 and 5, according to the present embodiment, it is possible to employ an elastic grounding piece 13 having an appropriate shape corresponding to the positional state of the grounding points 10p and the grounding portion 20p, and thus reliable grounding can be performed.

Also, because the elastic grounding piece 13 is formed in the lid portion 12, which has a greater surface area than the outer circumferential portion 11, grounding to the grounding portion 20p of the electronic device 20 is very easy.

### Embodiment 3

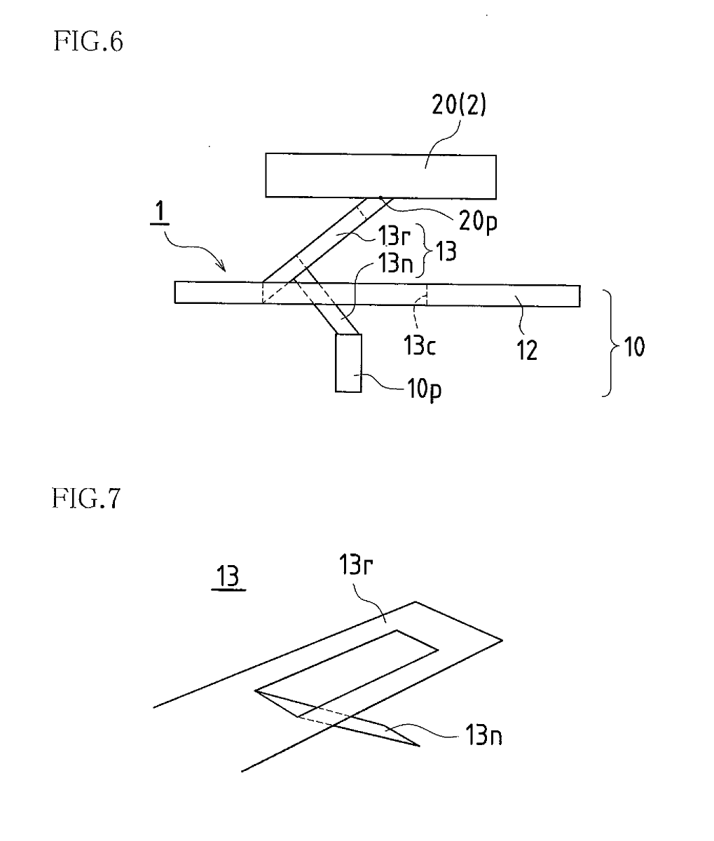

Embodiment 3 will be described with reference to FIGS. 6 to 9.

FIG. 6 is a side view that shows a state in which an outside tongue piece of an elastic grounding piece of an electronic tuner according to Embodiment 3 of the present invention has been grounded to a device component of an electronic device, and FIG. 7 is an enlarged perspective view that shows an enlargement of the elastic grounding piece of the electronic tuner according to Embodiment 3 of the present invention.

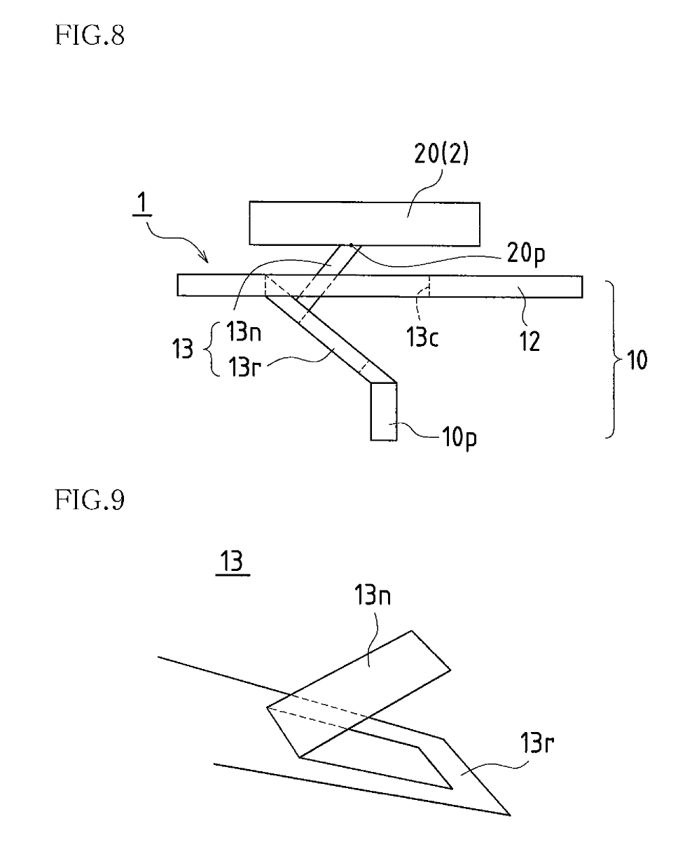

FIG. 8 is a side view that shows a state in which an inside tongue piece of the elastic grounding piece of the electronic tuner according to Embodiment 3 of the present invention has been grounded to the device component of the electronic device, and FIG. 9 is an enlarged perspective view that shows an enlargement of the elastic grounding piece of the electronic tuner according to Embodiment 3 of the present invention.

An elastic grounding piece 13 according to the present embodiment has an outside tongue piece 13r used to configure an outer circumference and an inside tongue piece 13n formed on the inside of the outside tongue piece 13r. As shown in FIGS. 6 to 9, the outside tongue piece 13r may contact the grounding portion 20p of the electronic component 2 (the device component 20) (FIGS. 6 and 7), and the inside tongue piece 13n may contact the grounding portion 20p of the electronic component 2 (the device component 20) (FIGS. 8 and 9). The basic configuration of the electronic tuner 1 according to the present embodiment is the same as in Embodiments 1 and 2, so mainly the differing points will be described here.

The elastic grounding piece 13 of the electronic tuner 1 shown in FIGS. 6 and 7 has an outside tongue piece 13r used to configure an outer circumference and an inside tongue piece 13n likewise formed on the inside of the outside tongue piece 13r, and the outside tongue piece 13r and the inside tongue piece 13n are each bent in an appropriate direction (opposite directions) so that the outside tongue piece 13r makes contact with the grounding portion 20p, and the inside tongue piece 13n makes contact with the grounding point 10p on the inside of the case 10.

That is, a configuration is adopted in which, in a state with the inside tongue piece 13n disposed bent to the inside of the lid portion 12 (the case 10) the elastic grounding piece 13 (the outside tongue piece 13r) is caused to protrude to the outside of the case 10 (the lid portion 12).

With this configuration, it is possible to obtain grounding to the grounding portion 20p with the elastic grounding piece 13 (the outside tongue piece 13r) having a simple structure and a comparatively large surface area, and it is possible to obtain grounding according to the state of the grounding portion 20p and the grounding point 10p. The elastic grounding piece 13 of the electronic tuner 1 shown in FIGS. 8 and 9 has an outside tongue piece 13r used to configure an outer circumference and an inside tongue piece 13n likewise formed on the inside of the outside tongue piece 13r, and the outside tongue piece 13r and the inside tongue piece 13n are each bent in an appropriate direction (opposite directions) so that the outside tongue piece 13r makes contact with the grounding point 10p on the inside of the case 10, and the inside tongue piece 13n makes contact with the grounding portion 20p.

That is, a configuration is adopted in which, in a state with the outside tongue piece 13r disposed bent to the inside of the lid portion 12 (the case 10), the elastic grounding piece 13 (the inside tongue piece 13n) is caused to protrude to the outside of the case 10 (the lid portion 12).

With this configuration, it is possible to obtain grounding to the grounding point 10p with an elastic grounding piece (an outside tongue piece) that has a simple structure and a comparatively large surface area, and it is possible to obtain grounding according to the state of the grounding portion 20p and the grounding point 10p.

Also, because the elastic grounding piece 13 is formed in the lid portion 12, which has a greater surface area than the outer circumferential portion 11, grounding to the grounding portion 20p of the electronic device 20 is very easy.

### Embodiment 4

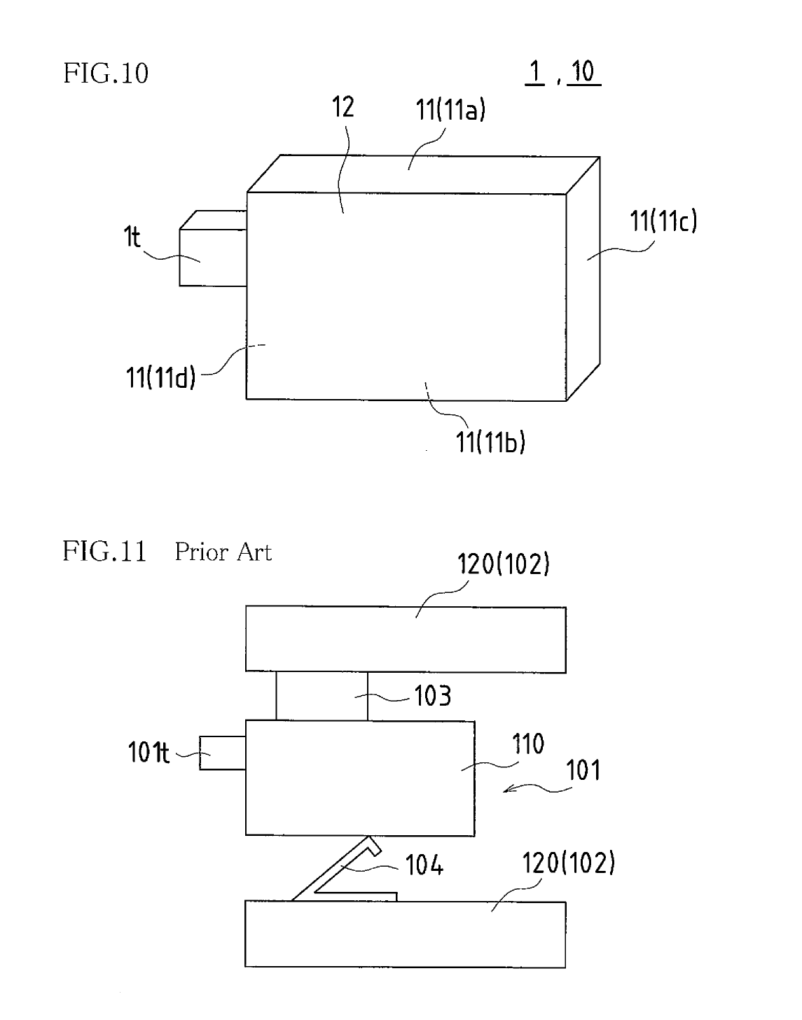

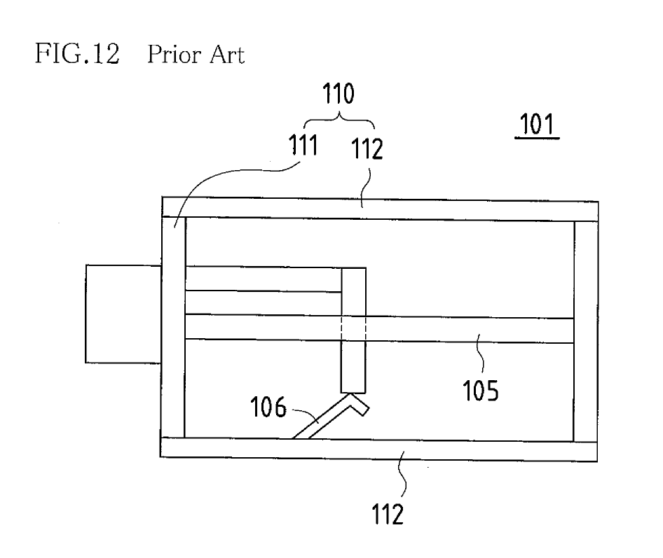

FIG. 10 is a perspective view that illustrates an electronic tuner according to Embodiment 4 of the present invention. Below, Embodiment 4 will be described with reference to FIG. 10.

The elastic grounding piece 13 according to Embodiments 1 to 3 was formed in a lid portion 12, but an elastic grounding piece 13 according to the present embodiment was formed in an outer circumferential portion 11.

The electronic tuner 1 shown in FIG. 10 is provided with a frame-like outer circumferential portion 11 (in FIG. 10, an outer circumferential portion 11a positioned in an upper face direction relative to the tuner terminal 1t, an outer circumferential portion 11b positioned in a lower face direction relative to the tuner terminal 1t, an outer circumferential portion 11c positioned in a back face direction relative to the tuner terminal it, and an outer circumferential portion 11d positioned in the same direction as the tuner terminal 1t; when it is not necessary to distinguish these, they are referred to as the outer circumferential portion 11). In the present embodiment, it is possible to have compatibility with a ground location or a groundable location that changes depending on the status of a tuner substrate contained in the electronic tuner 1 and an electronic device 2 equipped with the electronic tuner 1.

That is, in the present embodiment, a configuration is adopted in which the elastic grounding piece 13 is formed in the outer circumferential portion 11 (not shown). When the elastic grounding piece 13 is formed in the outer circumferential portion 11, the basic configuration is the same as when the elastic grounding piece 13 is formed in a lid portion 12, which is disclosed in Embodiments 1 to 3, and so a detailed description thereof is omitted here.

Ordinarily, the outer circumferential portion 11 has a smaller surface area that the lid portion 12, so it is necessary that the shape of the elastic grounding piece 13 is formed somewhat smaller than in Embodiments 1 to 3, but the basic configuration is the same, and the same working effects are obtained.

With this configuration, in all directions of the frame shape of the outer circumferential portion 11, it is possible to obtain grounding to the grounding portion 20p of the electronic device 2 (the device portion 20), and so it is possible to obtain appropriate grounding that corresponds to the position of the grounding portion 20p and the grounding point 10p.

### Embodiment 5

The present embodiment relates to an electronic device 2 (not shown) equipped with an electronic tuner 1 as described in Embodiments 1 to 4. The present embodiment will be described with reference to FIGS. 1 to 10.

As described by way of example in Embodiments 1 to 3 (FIGS. 1 to 5), a configuration is adopted in which an electronic device 2 is equipped with an electronic tuner 1. Accordingly, the electronic device 2 according to the present embodiment can be equipped with an electronic tuner 1 according to the present invention. With this configuration, the electronic device 2 according to the present embodiment is equipped with an electronic tuner 1 in which grounding is reinforced, and so it is possible for the electronic device 2 to have grounding with high reliability.

The present invention may be embodied in various other forms without departing from the gist or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. An electronic tuner comprising a case having a frame-like outer circumferential portion and a lid portion that covers a space formed by the outer circumferential portion,
wherein an elastic grounding piece formed by cutting open a portion of the case in the shape of a tongue piece is caused to protrude to the outside of the case, thus grounding the elastic grounding piece to a grounding portion of an external electronic device.

2. The electronic tuner according to claim 1, wherein the elastic grounding piece comprises a bent portion between a tip portion and a base, the tip portion being put in contact with the grounding portion, and the bent portion being put in contact with a grounding point inside of the case.

3. The electronic tuner according to claim 1, wherein the elastic grounding piece comprises a bent portion between a tip portion and a base, the tip portion being put in contact with a grounding point inside of the case, and the bent portion being put in contact with the grounding portion.

4. The electronic tuner according to claim 1, wherein the elastic grounding piece comprises an outside tongue piece used to configure an outer circumference and an inside tongue piece formed on the inside of the outside tongue piece, the outside tongue piece being put in contact with the grounding portion, and the inside tongue piece being put in contact with a grounding point on the inside of the case.

5. The electronic tuner according to claim 1, wherein the elastic grounding piece comprises an outside tongue piece used to configure an outer circumference and an inside tongue piece formed on the inside of the outside tongue piece, the outside tongue piece being put in contact with a grounding point on the inside of the case, and the inside tongue piece being put in contact with the grounding portion.

6. The electronic tuner according to claim 2, wherein the elastic grounding piece is formed in the lid portion.

7. The electronic tuner according to claim 2, wherein the elastic grounding piece is formed in the outer circumferential portion.

8. An electronic device equipped with an electronic tuner comprising a case, the electronic tuner being the electronic tuner according to claim 1.

9. The electronic tuner according to claim 3, wherein the elastic grounding piece is formed in the lid portion.

10. The electronic tuner according to claim 4, wherein the elastic grounding piece is formed in the lid portion.

11. The electronic tuner according to claim 5, wherein the elastic grounding piece is formed in the lid portion.

12. The electronic tuner according to claim 3, wherein the elastic grounding piece is formed in the outer circumferential portion.

13. The electronic tuner according to claim 4, wherein the elastic grounding piece is formed in the outer circumferential portion.

14. The electronic tuner according to claim 5, wherein the elastic grounding piece is formed in the outer circumferential portion.

15. An electronic device equipped with an electronic tuner comprising a case, the electronic tuner being the electronic tuner according to claim 2.

16. An electronic device equipped with an electronic tuner comprising a case, the electronic tuner being the electronic tuner according to claim 3.

17. An electronic device equipped with an electronic tuner comprising a case, the electronic tuner being the electronic tuner according to claim 4.

18. An electronic device equipped with an electronic tuner comprising a case, the electronic tuner being the electronic tuner according to claim 5.

19. An electronic device equipped with an electronic tuner comprising a case, the electronic tuner being the electronic tuner according to claim 6.

20. An electronic device equipped with an electronic tuner comprising a case, the electronic tuner being the electronic tuner according to claim 7.
